(19) United States
(12) Patent Application Publication
(10) Pub. No.: US 2008/0042146 A1
(43) Pub. Date: Feb. 21, 2008

(54) LIGHT-EMITTING DEVICE HAVING IMPROVED AMBIENT CONTRAST

(76) Inventors: Ronald S. Cok, Rochester, NY (US); Andrew D. Arnold, Hilton, NY (US)

Correspondence Address: Patent Legal Staff;Eastman Kodak Company, 343 State Street, Rochester, NY, 14650-2201, US

(21) Appl. No.: 11/465,691

(22) Filed: Aug. 18, 2006

(51) Int. Cl. H01L 31/12; H01L 29/20; H01L 29/22; H01J 1/62

(52) U.S. Cl. 257/79; 257/89; 257/98; 257/E33.001; 313/503

(57) ABSTRACT

A light emitting device comprising one or more color-change material light-emitting elements, wherein at least one color-change material light-emitting element comprises: a light-emitting layer that emits light including a first frequency range; a light-reflecting layer or surface that reflects light including at least the first frequency range positioned relatively beneath the light-emitting layer; a first color filter positioned relatively above the light-reflecting layer; and a color-change material positioned relatively over the light-emitting layer and over the first color filter; wherein the first color filter passes light having a second frequency range that includes the first frequency range, and not passing a range of visible light having a frequency lower than the first frequency range, and the color-change material converting light of the first frequency range to a third frequency range, the third frequency range including the range of visible light having a frequency lower than the first frequency range not passed by the first color filter. In a preferred embodiment of the invention, the device may comprise a full-color organic light-emitting diode (OLED) device.

### FIELD OF THE INVENTION

The present invention relates to light-emitting devices including color change materials, and more particularly, to display device structures for improving the ambient contrast of such devices.

### BACKGROUND OF THE INVENTION

Flat-panel display devices employ a variety of technologies for emitting patterned, colored light to form full-color pixels. Some of these technologies employ a common light-emitter for all of the color pixels and color-change materials to convert the light of the common light-emitter into colored light of the desired frequencies. Such unpatterned, common light-emitters may be preferred since patterning colored emitters can be difficult. For example, liquid crystal displays (LCDs) typically employ a backlight that relies on either fluorescent tubes to emit a white light or a set of differently colored, inorganic light-emitting diodes to emit white light together with patterned color filters, for example red, green, and blue, to create a full-color display. It is also known to employ the differently colored light-emitting diodes in the set sequentially to create a series of colored backlights in which case color filters may not be necessary. Alternatively, organic light-emitting diodes (OLEDs) may employ a combination of differently colored emitters, or an unpatterned broad-band emitter to emit white light together with patterned color filters, for example red, green, and blue, to create a full-color display. The color filters may be located on the substrate, for a bottom-emitter, or on the cover, for a top-emitter. For example, U.S. Pat. No. 6,392,340 entitled “Color Display Apparatus having Electroluminescence Elements” issued May 21, 2002 illustrates such a device. However, such designs are relatively inefficient since approximately two-thirds of the light emitted may be absorbed by the color filters.

OLEDs rely upon thin-film layers of organic materials coated upon a substrate. OLED devices generally can have two formats known as small molecule devices such as disclosed in U.S. Pat. No. 4,476,292 and polymer OLED devices such as disclosed in U.S. Pat. No. 5,247,190. Either type of OLED device may include, in sequence, an anode, an organic EL element, and a cathode. The organic EL element disposed between the anode and the cathode commonly includes an organic hole-transporting layer (HTL), an emissive layer (EL) and an organic electron-transporting layer (ETL). Holes and electrons recombine and emit light in the EL layer. Tang et al. (Appl. Phys. Lett., 51, 913 (1987), Journal of Applied Physics, 65, 3610 (1989), and U.S. Pat. No. 4,769,292) demonstrated highly efficient OLEDs using such a layer structure. Since then, numerous OLEDs with alternative layer structures, including polymeric materials, have been disclosed and device performance has been improved.

Light is generated in an OLED device when electrons and holes that are injected from the cathode and anode, respectively, flow through the electron transport layer and the hole transport layer and recombine in the emissive layer. Many factors determine the efficiency of this light generating process. For example, the selection of anode and cathode materials can determine how efficiently the electrons and holes are injected into the device; the selection of ETL and HTL can determine how efficiently the electrons and holes are transported in the device, and the selection of EL can determine how efficiently the electrons and holes be recombined and result in the emission of light, etc.

In yet another alternative means of providing a full-color OLED device, an OLED device may employ a single relatively high-frequency light emitter together with color-change materials (also known as color conversion layers) to provide a variety of color light output. The color-change materials absorb the relatively high-frequency light and re-emit light at relatively lower frequencies. For example, an OLED device may emit blue light suitable for a blue sub-pixel and employ a green color-change materials to absorb blue light to emit green light and employ a red color change materials to absorb blue and/or green light to emit red light. The color-change materials may be combined with color filters to further improve the color of the emitted light and to absorb incident light and avoid exciting the color-change materials with ambient light, thereby improving device contrast. US20050116621 A1 entitled “Electroluminescent devices and methods of making electroluminescent devices including a color conversion element” describes the use of color-change materials (or color-conversion elements).

U.S. Patent Application 20040233139A1 discloses a color conversion member which is improved in the prevention of a deterioration in color conversion function, the prevention of reflection of external light, and color rendering properties. The color conversion member comprises a transparent substrate, two or more types of color conversion layers, and a color filter layer. The color conversion layers function to convert incident lights for respective sub-pixels to outgoing lights of colors different from the incident lights. The two or more types of color conversion layers are arranged on said transparent substrate. The color filter layer is provided on the transparent substrate side of any one of the color conversion layers or between the above any one of the color conversion layers and the color conversion layers adjacent to the above any one the color conversion layers. US 20050057177 also describes the use of color change materials in combination with color filters.

It is also known to employ color-change materials in concert with micro-cavity structures having blue or blue-green emitters as described in U.S. Pat. No. 6,111,361. In this arrangement, a blue color filter is provided to purify the light from the blue sub-pixels, while color-change materials are provided to emit the green and red light in response to blue or blue-green light absorption. U.S. 2005/0140275A1 describes the use of red, green, and blue conversion layers for converting white light into three primary color of red, green, and blue light.

Referring to FIG. 2, a side view of a device employing color filters and color-change materials is illustrated. In FIG. 2, an active-matrix, top-emitting OLED device as suggested in the prior art is constructed on a substrate 10. Thin-film electronic components 30 are separated from a patterned, reflective electrode 12 by insulating and planarizing layers 32 and 34. One or more light-emitting organic layer(s) 14 are formed over the patterned, reflective electrode 12 and a second, transparent electrode 16 formed over the organic layer(s). The one or more light-emitting organic layer(s) 14 emit a blue light or a broadband light including blue light into a color change material layer having elements 42R that converts incident light into red light and elements 42G that converts incident light into green light. The converted red light then passes through color filter 44R, the converted green light passes through color filter 44G, and the emitted blue light passes through color filter 44B. A plurality of such color light-emitting elements may be grouped into pixels to form a display device. However, in all these designs, ambient contrast is still a problem, particularly in high-ambient light environments.

There is a need therefore for an improved organic light-emitting diode device structure comprising color-change material light-emitting elements that improves the ambient contrast of the device.

### SUMMARY OF THE INVENTION

In accordance with one embodiment, the invention is directed towards a light emitting device comprising one or more color-change material light-emitting elements, wherein at least one color-change material light-emitting element comprises: a light-emitting layer that emits light including a first frequency range; a light-reflecting layer or surface that reflects light including at least the first frequency range positioned relatively beneath the light-emitting layer; a first color filter positioned relatively above the light-reflecting layer; and a color-change material positioned relatively over the light-emitting layer and over the first color filter; wherein the first color filter passes light having a second frequency range that includes the first frequency range, and not passing a range of visible light having a frequency lower than the first frequency range, and the color-change material converting light of the first frequency range to a third frequency range, the third frequency range including the range of visible light having a frequency lower than the first frequency range not passed by the first color filter. In a preferred embodiment of the invention, the device may comprise a full-color organic light-emitting diode (OLED) device.

### ADVANTAGES

The present invention has the advantage that it improves the ambient contrast of light-emitting devices comprising color-change material light-emitting elements.

### BRIEF DESCRIPTION OF THE DRAWINGS

FIG. 1 illustrates a cross section of an active-matrix top-emitter OLED device having color filters and color-change materials according to one embodiment of the present invention;

FIG. 2 illustrates a cross section of an active-matrix top-emitter OLED device having a color filter and color-change materials suggested by the prior art;

FIG. 3 illustrates a cross section of an active-matrix top-emitter OLED device having color filters, color-change materials, and a scattering layer according to an alternative embodiment of the present invention;

FIG. 4 illustrates a cross section of an active-matrix top-emitter OLED device having color filters and color-change materials according to another embodiment of the present invention;

FIG. 5 illustrates a cross section of an active-matrix top-emitter OLED device having color filters, color-change materials, and a scattering layer according to an alternative embodiment of the present invention;

FIG. 6 illustrates a cross section of a top-emitter LCD device having a backlight unit, color-change medium layer, and color filters according to yet another embodiment of the present invention; and

FIG. 7 illustrates a cross section of an active-matrix top-emitter OLED device having another arrangement of color filters, color-change materials, and a scattering layer according to an alternative embodiment of the present invention.

FIG. 8 illustrates a cross section of an active-matrix top-emitter OLED device having another arrangement of color filters and color-change materials according to an alternative embodiment of the present invention.

It will be understood that the figures are not to scale since the individual layers are too thin and the thickness differences of various layers too great to permit depiction to scale.

### DETAILED DESCRIPTION OF THE INVENTION

Referring to FIG. 1, a light emitting device comprises one or more color-change material light-emitting elements 50R, 50G, or 50B formed on a substrate 10 and encapsulated by a transparent cover 20. In the embodiment of FIG. 1, each color-change material light-emitting element 50R, 50G, and 50B comprises a light-emitting layer 14 that emits light including a first frequency range, positioned between lower and upper electrodes 12 and 14, where the lower electrode 12 comprises a light-reflecting layer or surface that reflects light including at least the first frequency range; a first color filter 40A, 40B, or 40C formed over the light-emitting layer 14, the first color filter passing light having a second frequency range that includes the first frequency range, and not passing a range of visible light having a frequency lower than the first frequency range; and a color-change material 42R, 42G, or 42B formed over the first color filter 40A, 40B, or 40C that converts light of the first frequency range to a third frequency range, the third frequency range including the range of visible light having a frequency lower than the first frequency range not passed by the first color filter 40A, 40B, or 40C. Thus, light-reflecting layer or surface of electrode 12 is positioned relatively beneath the light-emitting layer 14; first color filter 40A/40B/40C is positioned relatively above the light-reflecting layer 12; and color-change material 42R/42B/42G is positioned relatively over the light-emitting layer 14 and over the first color filter 40A/40B/40C.

In accordance with a preferred embodiment of the present invention, the device further comprises a second color filter 44R, 44G, or 44B formed over the color-change material 42R, 42G, or 42B, the second color filter 44R, 44G, or 44B passing light including at least a portion of the range of visible light having a frequency lower than the first frequency range not passed by the first color filter 40A, 40B, or 40C, and not passing at least a portion of visible light passed by the first color filter 40A, 40B, or 40C.

As used herein, a color filter is a layer comprised of light-absorptive material that strongly absorbs light of one frequency range but largely transmits light of a different frequency range. For example, a red color filter will mostly absorb green- and blue-colored light while mostly transmitting red-colored light. Such color filter materials typically comprise pigments and dyes. As used herein, a color-change material (CCM), also known as a color-conversion layer, is a layer of material that absorbs light of one frequency range and re-emits light at a second, lower frequency range. Such materials are typically fluorescent or phosphorescent. Both materials are known in the prior art, however the color-change materials are occasionally referred to as color filters. In the present invention, the term color filter is employed to refer to materials that primarily absorb or transmit light of selected frequencies, rather than to materials that convert light of one frequency to another.

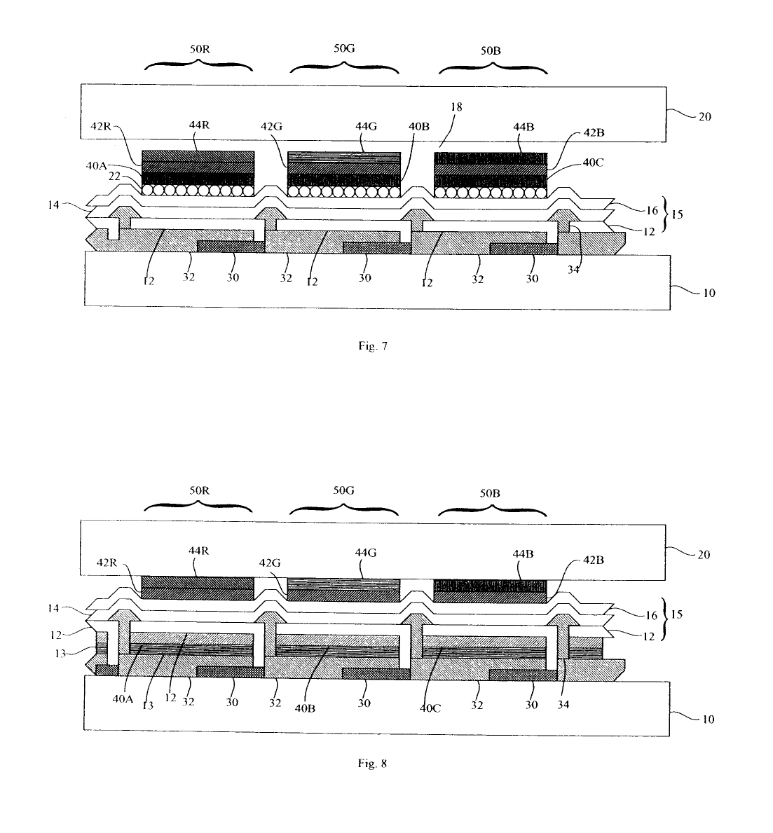

A variety of light-emitting layers may be employed in the present invention. For example, the light-emitting layer 14 may comprise one or more layers of light-emitting organic or inorganic material. As shown in FIG. 1, such light-emitting material layer may be positioned between first and second electrodes 12 and 16, with at least one electrode being transparent, thereby forming a light-emitting diode unit 15. In the top-emitting configuration of FIG. 1, thin-film electronic components 30 formed on a substrate 10 are separated from a patterned, reflective electrode 12 by insulating and planarizing layers 32 and 34. One or more un-patterned light-emitting organic layer(s) 14 are formed over the patterned, reflective electrode 12 and a second, un-patterned, transparent electrode 16 formed over the organic layer(s) 14. Alternatively, as shown in FIG. 6, the light-emitting layer 14 of the device may comprise a backlight unit 62, that may be employed together with a transmissive liquid crystal device 64 having two electrodes and a layer of liquid crystal materials located between the electrodes. In this embodiment, the backlight unit may comprise an inorganic light-emitting diode (LED) 60 that emits, for example, blue light.

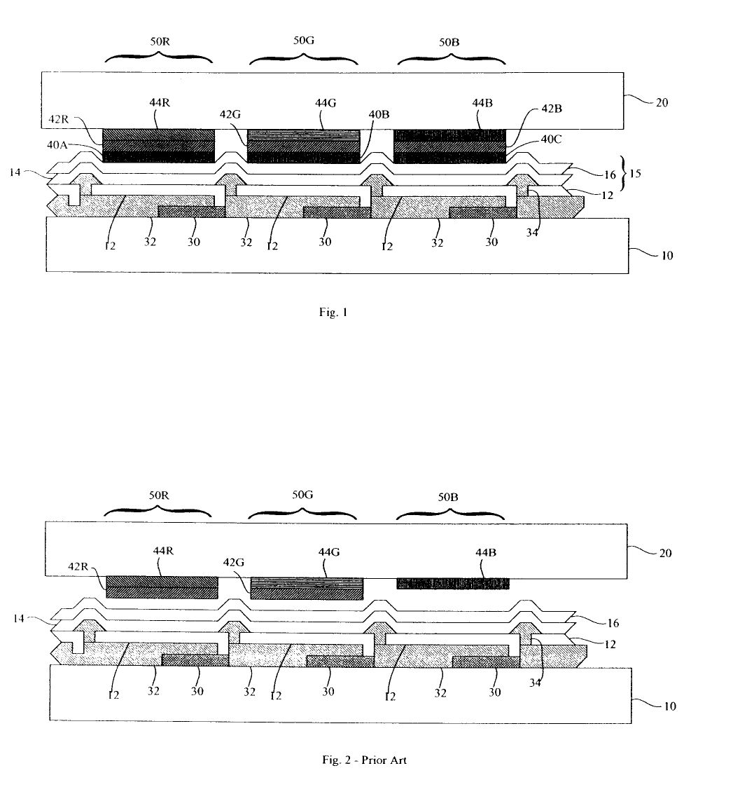

In the OLED embodiment of FIG. 1, when stimulated by a current controlled by the thin-film electronic components 30, the light-emitting layer 14 may emit an ultra-violet light, a blue light, or a broadband light (for example a white light) including blue light or ultra-violet light, through the color filters 40A/40B/40C. These color filters pass at least the blue or ultra-violet light into the color conversion layer 42R/42G/42B. The color conversion layer 42R converts the incident blue or ultra-violet light into red light for red light-emitting element 50R, color conversion layer 42G converts the incident blue or ultra-violet light into green light for green light-emitting element 50G, and color conversion layer 42B converts the incident blue or ultra-violet light into blue light for blue light-emitting element 50B. Since the light-emitting layer 14 may itself emit blue light, the color conversion layer 42B and color filters 40C and/or 44B may be omitted for the blue light-emitting element 50B (as shown in FIG. 4 with respect to color filter 40C). In this case, the blue light-emitting element 50B may also be formed as a conventional blue pixel having a blue light-emitting organic or inorganic materials with only a blue color filter 44B, as illustrated in FIG. 2. Such a light-emitting element is considered herein as a non-color-change light-emitting element. Alternatively, as shown in FIG. 1, if the light-emitting layer 14 emits ultra-violet light, the blue light-emitting element 50B may include a color-conversion layer 42B along with a color filter 40C that passes UV light. In each case, an additional color filter 44R/44G/44B may be employed as trimming filters to further control the converted or emitted color and to absorb ambient light. This absorption of ambient light will also have the beneficial effect of reducing any stimulation of the color-conversion layer by ambient light improving contrast.

The present invention is improved over the prior art by the addition of color filters 40A/40B/40C. In the simplest case, where light-emitting layer 14 emits blue light, color filters 40A and 40B may comprise common blue color filters, along with use of a blue color filter 40C and/or 44B. While such filters 40A/40B will pass the light emitted by the light-emitting layer 14 so that it may be converted to red or green light and emitted through transparent cover 20, ambient red light that passes through the color filter 44R and ambient green light that passes through the color filter 44G will be absorbed by the blue color filters 40A and 40B so that, effectively all ambient light incident on light-emitting element 50R is absorbed by the combination of a red color filter 44R and blue color filter 40A while all ambient light incident on light-emitting element 50G is absorbed by the combination of a green color filter 44G and blue color filter 40B. While the blue portion of ambient light incident on light-emitting element 50B may still be reflected, the overall reflection from the light-emitting portions of the device is reduced from 33% to 11%. While the color filters 40A and 40B may also absorb light emitted by the color change materials 42, this is preferable to the use of an black absorptive layer or electrode 12 to absorb ambient light since such an absorptive layer would absorb light from both the color change materials 42 and the light emitting layer 14.

While in one embodiment of the present invention the color filter 40A, 40B, and optional color filter 40C comprise common materials and a common color filter, in an alternative embodiment, the color filter 40A can be a cyan color filter. In this embodiment, the combination of red color filter 44R still combines with cyan color filter 40A to absorb all incident ambient light, but any green light emitted by the light-emitting layer 14 can be employed to stimulate the red color-conversion layer 42R to emit red light, thereby increasing the efficiency of the red light-emitting element 50R.

The light-emitting elements 50 of the present invention may be independently controlled and grouped into full-color pixels and a plurality of such pixels provided to form a display device. A common first color filter and light-emitting layer may be employed for all of the elements in each pixel or for all of the elements in the display. The common first color filter may be a blue color filter while the light-emitting layer may emit blue or ultra-violet colored light, or both frequency ranges of light. The display device may have two independently controllable light-emitting elements that emit red and green light respectively and employ color filters and color conversion layers according to the present invention and a third independently controllable light-emitting element that emits blue light and optionally includes a color filter and color conversion layer.

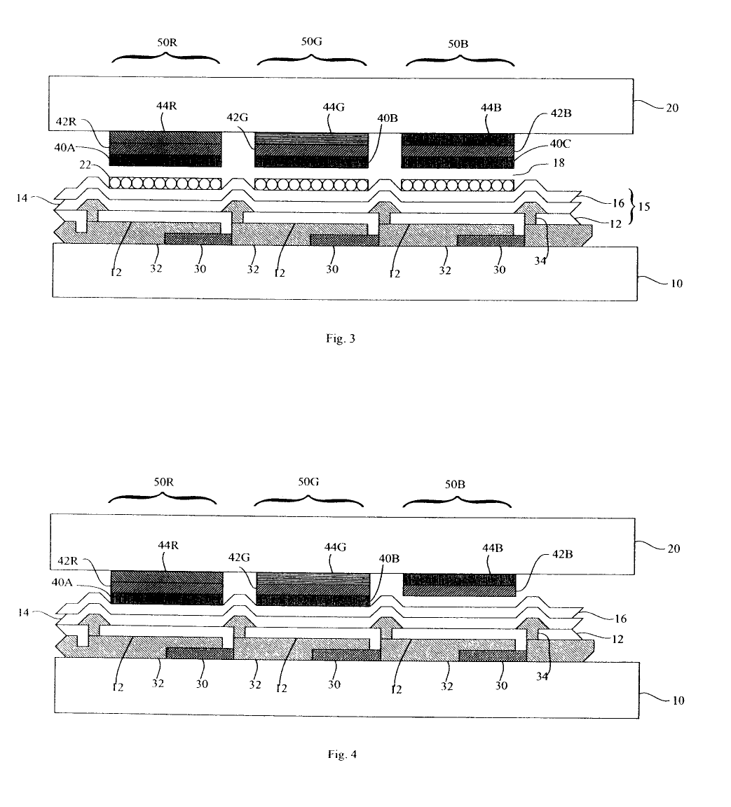

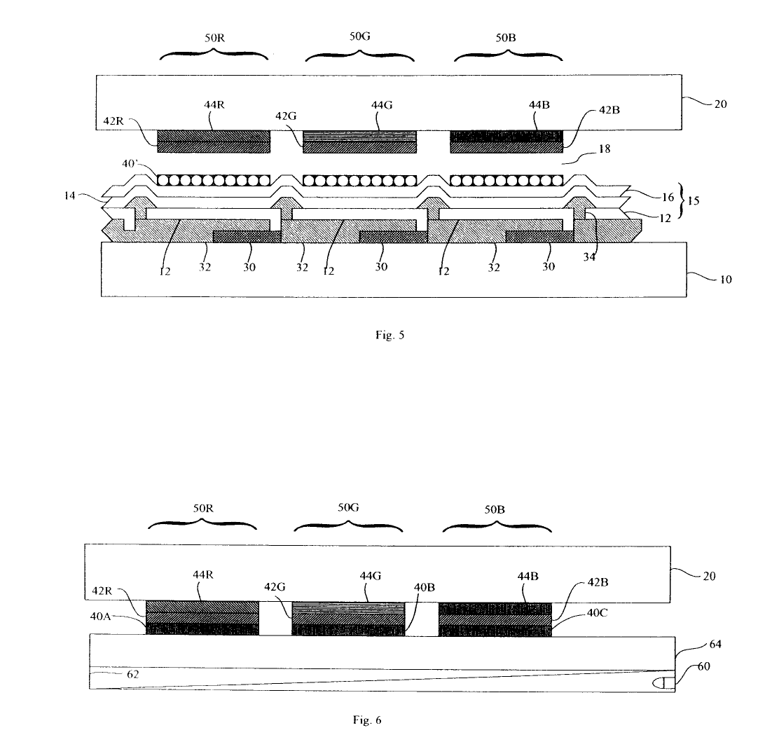

As illustrated in FIG. 3, in a further preferred embodiment of the present invention, the light-emitting layer 14 may be part of an OLED device employed with a scattering layer 22 located adjacent to, or within, the light-emitting layer 14 to increase the light emitted from the OLED device as is described in co-pending, commonly assigned U.S. Ser. No. 11/065,082 filed Feb. 24, 2005, the disclosure of which is incorporated herein by reference. The scattering layer 22 extracts trapped light from within the OLED organic and electrode layers. A low-index element 18 serves to optically isolate the cover 20, color filters 40, 44, and color-conversion layers 42 and thereby maintain the sharpness of a pixilated display device. The scattering layer may be integrated with the first color filters, to form light-scattering color filters 40′, as shown in FIG. 5.

In this embodiment, the light-emissive layer(s) 14 have a first refractive index range, and the transparent cover 20 through which light from the OLED is emitted has a second refractive index. A light scattering layer 22 may be optically coupled to the transparent electrode to extract light that would otherwise be trapped in the organic layer(s) 14 and transparent electrode. A transparent low-index element 18 having a third refractive index at least lower than the second refractive index and preferably lower than each of the first refractive index range and second refractive index may be located between the scattering layer 22 and the cover 20. The low-index element 18 may be located between the scattering layer 22 and the first color filter 40 (as depicted in FIG. 3), or between the color filters and the cover 20 (as depicted in FIG. 7). Alternatively, the low-index element 18 may be located between the color filters 40 or 44 and the color-conversion layer 42 (not shown). Light incident at any angle on the scattering layer may be scattered into an angle that allows the light to enter the low-index layer 18. Because the low-index element 18 has a lower optical index than the cover 20, light that passes into the low-index element 18 cannot be trapped in the cover 20 and thus escapes from the OLED device. Emitted or re-emitted light that does not enter into the low-index medium 18 will re-enter the scattering layer 22 and be re-scattered until it eventually escapes. Light re-scattered toward the substrate can be reflected back and scattered again. It is likewise preferred that the low-index element 18 have an optical index lower than that of the color filters 40 and 44 and color conversion layer 42 so that if light passes from the low-index medium into the color filters 40 and 44 and color conversion layer 42, it will escape from the device.

Light that is emitted by the color-conversion layer 42 is likewise emitted in all directions. Some light may be emitted back toward the color filters 40 and be absorbed; the remainder may be emitted from the OLED device. Although some light is thus lost to absorption, the reduction in reflectivity of the device due to the absorption of ambient light is greater than the loss in brightness, so that the ambient contrast is improved overall.

In various embodiments, the present invention may be in a top-emitter configuration (as shown in FIG. 1) or a bottom-emitter configuration (not shown). In the top-emitter configuration of FIG. 1, light is emitted through the cover 20, the electrode 16 and cover 20 are typically transparent while the electrode 12 is reflective and the substrate 10 may be opaque, reflective, absorptive, or transparent. In a bottom-emitter configuration, light is emitted through the substrate 10, the electrode 12 and substrate 10 are typically transparent while the electrode 16 is reflective and the cover 20 may be opaque, reflective, absorptive, or transparent. In a typical configuration, the color-change materials 22, the scattering layer 18, and low-index layer 18 are located on the side of the transparent electrode opposite the organic layers 14 and may be formed photolithographically and/or may employ inkjet deposition.

In the various embodiments discussed above, the first color filter 40 is positioned relatively above the light-emitting layer 14, which is relatively above light-reflecting electrode layer 12. Alternatively, as shown in FIG. 8, first color filter 40 may be positioned between a light-reflecting layer 13 and the light-emitting layer 14. In such embodiment, lower electrode 12 may be transparent, such as comprising ITO, and light reflecting layer 13 may comprise a metallic layer comprising, e.g., aluminum or silver. The embodiment of FIG. 8 may be particularly useful in combination with a white-light emitting layer 14, since in such case a portion of the light of the second frequency range may be usefully emitted without being absorbed by the first color filters 40.

Light absorbing, black-matrix materials may also be employed between light-emitting elements 50, for example in a common layer between the color filters 40 or 44 or color change material layers 42, to further improve the absorption of ambient light. Such black-matrix materials may be formed from carbon black in a polymeric binder and located either on the cover 20 or formed on the OLED and employed to separate patterned color filters or color-change materials. Black-matrix materials are well-known and may, for example, comprise a polymer or resin with carbon black.

OLED protective layers may also be employed over the OLED organic layer(s) 14 and transparent electrode 16 to protect the OLED from environmental contamination such as water vapor or mechanical stress. In such cases, the scattering layer may be located over the protective layers.

In preferred embodiments, the cover 20 and substrate 10 may comprise glass or plastic with typical refractive indices of between 1.4 and 1.6. The transparent low-index element 18 may comprise a solid layer of optically transparent material, a void, or a gap. Voids or gaps may be a vacuum or filled with an optically transparent gas or liquid material. For example air, nitrogen, helium, or argon all have a refractive index of between 1.0 and 1.1 and may be employed. Lower index solids which may be employed include fluorocarbon or MgF, each having indices less than 1.4. Any gas employed is preferably inert. Reflective electrode 12 is preferably made of metal (for example aluminum, silver, or magnesium) or metal alloys. Transparent electrode 16 is preferably made of transparent conductive materials, for example indium tin oxide (ITO) or other metal oxides. The organic material layer(s) 14 may comprise organic materials known in the art, for example, hole-injection, hole-transport, light-emitting, electron-injection, and/or electron-transport layers. Such organic material layers are well known in the OLED art. The organic material layer(s) 14 typically have a refractive index of between 1.6 and 1.9, while indium tin oxide has a refractive index of approximately 1.8-2.1. Hence, the various organic and transparent electrode layers in the OLED have a refractive index range of 1.6 to 2.1. Of course, the refractive indices of various materials may be dependent on the wavelength of light passing through them, so the refractive index values cited here for these materials are only approximate. In any case, the transparent low-index element 18 preferably has a refractive index at least 0.1 lower than that of each of the first refractive index range and the second refractive index at the desired wavelength for the OLED emitter.

Scattering layer 22 may comprise a volume scattering layer or a surface scattering layer. In certain embodiments, e.g., scattering layer 22 may comprise materials having at least two different refractive indices. The scattering layer 22 may comprise, e.g., a matrix of lower refractive index and scattering elements have a higher refractive index. Alternatively, the matrix may have a higher refractive index and the scattering elements may have a lower refractive index. For example, the matrix may comprise silicon dioxide or cross-linked resin having indices of approximately 1.5, or silicon nitride with a much higher index of refraction. If scattering layer 22 has a thickness greater than one-tenth part of the wavelength of the emitted light, then it is desirable for the index of refraction of at least one material in the scattering layer 22 to be approximately equal to or greater than the first refractive index range. This is to insure that all of the light trapped in the organic layers 14 and transparent electrode 16 can experience the direction altering effects of scattering layer 22. If scattering layer 22 has a thickness less than one-tenth part of the wavelength of the emitted light, then the materials in the scattering layer need not have such a preference for their refractive indices.

In an alternative embodiment, scattering layer 22 may comprise particles deposited on another layer, e.g., particles of titanium dioxide may be coated over transparent electrode 16 to scatter light. Preferably, such particles are at least 100 nm in diameter to optimize the scattering of visible light. In a further alternative, scattering layer 18 may comprise a rough, diffusely reflecting or refracting surface of electrode 12 or 16 itself.

The scattering layer 22 is typically adjacent to and in contact with, or close to, an electrode to defeat total internal reflection in the organic layers 14 and transparent electrode 16. However, if the scattering layer 22 is between the electrodes 12 and 16, it may not be necessary for the scattering layer to be in contact with an electrode 12 or 16 so long as it does not unduly disturb the generation of light in the OLED layers 14. According to an embodiment of the present invention, light emitted from the organic layers 14 can waveguide along the organic layers 14 and electrode 16 combined, since the organic layers 14 have a refractive index lower than that of the transparent electrode 16 and electrode 12 is reflective. The scattering layer 22 or surface disrupts the total internal reflection of light in the combined layers 14 and 16 and redirects some portion of the light out of the combined layers 14 and 16. To facilitate this effect, the transparent low-index element 18 should not itself scatter light, and should be as transparent as possible. The transparent low-index element 18 is preferably at least one micron thick to ensure that emitted light properly propagates through the transparent low-index element and is transmitted through the cover 20.

Whenever light crosses an interface between two layers of differing index (except for the case of total internal reflection), a portion of the light is reflected and another portion is refracted. Unwanted reflections can be reduced by the application of standard thin anti-reflection layers. Use of anti-reflection layers may be particularly useful on both sides of the encapsulating cover 20, for top emitters, and on both sides of the transparent substrate 10, for bottom emitters.

The scattering layer 22 can employ a variety of materials. For example, randomly located spheres of titanium dioxide may be employed in a matrix of polymeric material. Alternatively, a more structured arrangement employing ITO, silicon oxides, or silicon nitrides may be used. In a further embodiment, the refractive materials may be incorporated into the electrode itself so that the electrode is a scattering layer. Shapes of refractive elements may be cylindrical, rectangular, or spherical, but it is understood that the shape is not limited thereto. The difference in refractive indices between materials in the scattering layer 22 may be, for example, from 0.3 to 3, and a large difference is generally desired. The thickness of the scattering layer, or size of features in, or on the surface of, a scattering layer may be, for example, 0.03 to 50 μm. It is generally preferred to avoid diffractive effects in the scattering layer. Such effects may be avoided, for example, by locating features randomly or by ensuring that the sizes or distribution of the refractive elements are not the same as the wavelength of the color of light emitted by the device from the light-emitting area.

The scattering layer 22 should be selected to get the light out of the OLED as quickly as possible so as to reduce the opportunities for re-absorption by the various layers of the OLED device. If the scattering layer 22 is to be located between the organic layers 14 and the transparent low-index element 18, or between the organic layers 14 and a reflective electrode 12, then the total diffuse transmittance of the same layer coated on a glass support should be high (preferably greater than 80%). In other embodiments, where the scattering layer 22 is itself desired to be reflective, then the total diffuse reflectance of the same layer coated on a glass support should be high (preferably greater than 80%). In all cases, the absorption of the scattering layer should be as low as possible (preferably less than 5%, and ideally 0%).

Materials of the light scattering layer 22 can include organic materials (for example polymers or electrically conductive polymers) or inorganic materials. The organic materials may include, e.g., one or more of polythiophene, PEDOT, PET, or PEN. The inorganic materials may include, e.g., one or more of SiOₓ (x>1), SiNₓ (x>1), Si₃N₄, TiO₂, MgO, ZnO, Al₂O₃, SnO₂, In₂O₃, MgF₂, and CaF₂. The scattering layer 22 may comprise, for example, silicon oxides and silicon nitrides having a refractive index of 1.6 to 1.8 and doped with titanium dioxide having a refractive index of 2.5 to 3. Polymeric materials having refractive indices in the range of 1.4 to 1.6 may be employed having a dispersion of refractive elements of material with a higher refractive index, for example titanium dioxide.

Conventional lithographic means can be used to create the scattering layer using, for example, photo-resist, mask exposures, and etching as known in the art. Alternatively, coating may be employed in which a liquid, for example polymer having a dispersion of titanium dioxide, may form a scattering layer 22.

One problem that may be encountered with such scattering layers is that the electrodes may tend to fail open at sharp edges associated with the scattering elements in the layer 22. Although the scattering layer may be planarized, typically such operations do not form a perfectly smooth, defect-free surface. To reduce the possibility of shorts between the electrodes 12 and 16, a short-reduction layer may be employed between the electrodes. Such a layer is a thin layer of high-resistance material (for example having a through-thickness resistivity between 10⁻⁷ ohm-cm² to 10³ ohm-cm²). Because the short-reduction layer is very thin, device current can pass between the electrodes through the device layers but leakage current through the shorts are much reduced. Such layers are described in US2005/0225234, filed Apr. 12, 2004, the disclosure of which is incorporated herein by reference.

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890 issued May 8, 2001 to Boroson et al. In addition, barrier layers such as SiOₓ (x>1), Teflon, and alternating inorganic/polymeric layers are known in the art for encapsulation.

In particular, very thin layers of transparent encapsulating materials may be deposited on the electrode. In this case, the scattering layer 22 may be deposited over the layers of encapsulating materials. This structure has the advantage of protecting the electrode 16 during the deposition of the scattering layer 22. Preferably, the layers of transparent encapsulating material have a refractive index comparable to the first refractive index range of the transparent electrode 16 and organic layers 14, or is very thin (e.g., less than about 0.2 micron) so that wave guided light in the transparent electrode 16 and organic layers 14 will pass through the layers of transparent encapsulating material and be scattered by the scattering layer 22.

OLED devices of this invention can employ various well-known optical effects in order to enhance their properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing neutral density filters over the display. Filters, polarizers, and anti-glare or anti-reflection coatings may be specifically provided over the cover or as part of the cover.

The present invention may also be practiced with either active- or passive-matrix OLED devices. It may also be employed in display devices. In a preferred embodiment, the present invention is employed in a flat-panel OLED device composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device, including both active- and passive-matrix OLED displays having either a top- or bottom-emitter architecture. In further embodiments, the invention may be usefully employed with inorganic light-emitting diode units such as disclosed in U.S. Ser. No. 11/226,622, the disclosure of which is incorporated by reference herein.

Color change materials that may be employed in the present invention are themselves also well-known. Such materials are typically fluorescent and/or phosphorescent materials that absorb light at higher frequencies (shorter wavelengths, e.g. blue) and emit light at different and lower frequencies (longer wavelengths, e.g. green or red). Such materials that may be employed for use in OLED devices in accordance with the present invention are disclosed, e.g., in U.S. Pat. Nos. 5,126,214, 5,294,870, and 6,137,459, US2005/0057176 and US2005/0057177, the disclosures of which are incorporated by reference herein.

The invention has been described in detail with particular reference to certain preferred embodiments thereof, but it will be understood that variations and modifications can be effected within the spirit and scope of the invention.

### Parts List

10 substrate
12 electrode
14 light-emitting layer
15 light-emitting diode unit
16 electrode
18 low-index element
20 cover
22 scattering layer
30 thin-film transistors
32 planarization layer
34 planarization layer
40, 40A, 40B, 40C first color filters
40′ light-scattering color filter
42, 42R, 42G, 42B color-change material layer
44, 44R, 44G, 44B second color filters
50, 50R, 50G, 50B light-emitting elements
60 inorganic light-emitting diode
62 backlight unit
64 liquid crystal device

1. A light emitting device comprising one or more color-change material light-emitting elements, wherein at least one color-change material light-emitting element comprises:
a light-emitting layer that emits light including a first frequency range;
a light-reflecting layer or surface that reflects light including at least the first frequency range positioned relatively beneath the light-emitting layer;
a first color filter positioned relatively above the light-reflecting layer; and
a color-change material positioned relatively over the light-emitting layer and over the first color filter;
wherein the first color filter passes light having a second frequency range that includes the first frequency range, and not passing a range of visible light having a frequency lower than the first frequency range, and the color-change material converting light of the first frequency range to a third frequency range, the third frequency range including the range of visible light having a frequency lower than the first frequency range not passed by the first color filter.

2. The device of claim 1 further comprising a second color filter formed over the color-change material, the second color filter passing light including at least a portion of the range of visible light having a frequency lower than the first frequency range not passed by the first color filter, and not passing at least a portion of visible light passed by the first color filter.

3. The device of claim 1 wherein the color-change material light-emitting element comprises an OLED having first and second electrodes, at least one electrode being transparent, wherein the light-emitting layer comprises one or more layers of light-emitting organic material formed between the first and second electrodes.

4. The device of claim 3 wherein one of the electrodes of the OLED comprises the light-reflecting layer or surface positioned relatively beneath the light-emitting layer.

5. The device of claim 1, wherein the first color filter is positioned between the light-reflecting layer or surface and the light-emitting layer.

6. The device of claim 1, wherein the first color filter is positioned relatively above the light-emitting layer.

7. The device of claim 1 wherein the light-emitting layer comprises a backlight unit, and further comprises a transmissive liquid crystal device having two electrodes and a layer of liquid crystal materials located between the electrodes.

8. The device of claim 1 wherein the light-emitting layer comprises a layer of inorganic light-emitting material particles.

9. The device of claim 1 wherein the first frequency range is blue, the second frequency range is blue or cyan, and the third frequency range is green or red.

10. The device of claim 1 wherein the first frequency range is ultra-violet, the second frequency range is ultra-violet or ultra-violet with blue and/or cyan, and the third frequency range is blue, green, or red.

11. The device of claim 1 comprising a plurality of independently-controllable light-emitting elements forming a full-color display device.

12. The display device of claim 11 wherein the independently controllable light-emitting elements are grouped into full-color pixels, each having at least a red, a green, and a blue light emitting element.

13. The device of claim 11 wherein each of the independently-controllable light-emitting elements comprise a common first color filter.

14. The display device of claim 11 wherein the common first color filter is a blue color filter.

15. The display device of claim 11 wherein each of the independently-controllable light-emitting elements comprise a common light-emitting layer.

16. The display device of claim 11 wherein at least one of the independently-controllable light-emitting elements comprises a red color-change light-emitting element, and at least one of the independently-controllable light-emitting elements comprises a green color-change light-emitting element.

17. The display device of claim 16 further comprising a non-color-change light-emitting element that emits blue light.

18. The display device of claim 17 wherein the blue light-emitting element comprises a blue color filter.

19. The device of claim 1 wherein the light-emitting layer emits blue or ultra-violet light.

20. The device of claim 1 wherein the light-emitting layer emits white light.
